(19) United States
(12) Patent Application Publication
(10) Pub. No.: US 2007/0072413 A1
(43) Pub. Date: Mar. 29, 2007

(54) Methods of forming copper interconnect structures on semiconductor substrates

(76) Inventors: Seung-Man Choi, Fishkill, NY (US); Moosung Chae, Poughkeepsie, NY (US)

Correspondence Address: MYERS BIGEL SIBLEY & SAJOVEC, PO BOX 37428, RALEIGH, NC, 27627, US

(21) Appl. No.: 11/234,535

(22) Filed: Sep. 23, 2005

(51) Int. Cl. H01L 21/4763

(52) U.S. Cl. 438/645; 438/687; 438/675

(57) ABSTRACT

Methods of forming copper interconnect structures according to embodiments of the present invention include forming an electrically insulating layer having a recess therein on a semiconductor substrate and then forming a layer of copper having a thickness greater than about 3000 Å on an upper surface of the electrically insulating layer and in the recess. The layer of copper is then annealed. This annealing step may be a relatively low temperature anneal (i.e., “soft” anneal). After the initial anneal, the layer of copper is planarized for a sufficient duration to reduce a thickness of the layer of copper on the upper surface to a range from about 1000 Å to about 2000 Å. The planarized layer of copper is then annealed again and/or exposed to a plasma treatment. The duration and temperature of this step(s) (i.e., the total “thermal treatment”) is sufficient to cause the formation of grooves at grain boundaries within the layer of copper. Following this thermal treatment, the layer of copper is further planarized for a sufficient duration to remove the grooves and expose the upper surface of the electrically insulating layer and define a conductive copper pattern within the recess.

### FIELD OF THE INVENTION

The present invention relates to integrated circuit fabrication methods and, more particularly, to methods of fabricating integrated circuit devices having metal interconnect layers therein.

### BACKGROUND OF THE INVENTION

Conventional methods of forming integrated circuit devices may include steps to form single and dual damascene structures using copper (Cu) as an electrical interconnect material. These steps to form single and dual damascence structures may include forming a recess in an electrically insulating layer and then forming an electrically conductive barrier layer (e.g., TaN barrier layer) that extends on sidewalls of the recess. Thereafter, a copper seed layer may be formed on the barrier layer. This seed layer may be used to electroplate a copper layer that fills the recess and extends opposite an upper surface of the electrically insulating layer. The electroplated copper layer is then annealed to increase grain growth within the copper layer. A chemical-mechanical polishing (CMP) step is performed to planarize the electroplated copper layer and barrier layer in sequence. This CMP step is performed for a sufficient duration to expose the upper surface of the electrically insulating layer and define a copper interconnect structure within the recess. Unfortunately, this conventional method may result in a relatively high occurrence of stress-induced voiding (SIV) that may be caused by a relatively high temperature anneal. In particular, whereas insufficient annealing of the copper layer prior to polishing may result in substantial grain growth within the copper layer during thermal treatment steps that follow polishing, substantial annealing of the copper layer prior to polishing may induce or accelerate SIV. Theoretical and experimental analysis of SIV is disclosed more fully in an article by B. L. Park et al., entitled “Mechanism of Stress-induced Voids in Multi-Level Cu”, IEEE International Interconnect Technology Conference (2002). One technique to reduce SIV in a copper interconnect structure is disclosed in an article by T. Harada et al., entitled “Reliability Improvement of Cu Interconnects by Additional Anneal Between Cu CMP and Barrier CMP,” IEEE International Interconnect Technology Conference (2003).

Other conventional techniques for forming copper interconnect structures may result in the formation of parasitic voids caused by the presence of grooves at copper grain boundaries. Such techniques are disclosed in an article by S. J. Lee et al., entitled “New Insight Into Stress Induced Voiding Mechanism in Cu Interconnects,” IEEE International Interconnect Technology Conference (2005). As illustrated by FIGS. 1A-1D, a conventional method of forming a copper interconnect structure includes patterning a layer of photoresist 12 on an electrically insulating layer 10 and then etching a recess 13 in the electrically insulating layer 10 using the patterned layer of photoresist 12 as an etching mask. Thereafter, a copper layer 14 is formed on the electrically insulating layer 10. This copper layer 14, which extends into the recess 13, may be formed by electroplating the copper layer 14 from a seed layer (not shown). As illustrated by FIGS. 1C-1D, the copper layer 14 is planarized for a sufficient duration to expose the electrically insulating layer 10 and define a copper interconnect structure 14a within the recess 13. This planarization step may be performed by chemical-mechanical polishing an upper surface of the copper layer 14. A second electrically insulating layer 16 is deposited on the copper interconnect structure 14a. This second electrically insulating layer 16 may be a silicon oxynitride (SiON) layer that is deposited using a relatively high temperature deposition technique. Another relatively high temperature deposition technique may also be used to deposit a third electrically insulating layer 18 on the second electrically insulating layer 16. This third electrically insulating layer 18 may be a SiCOH layer. Unfortunately, the deposition of the second and third electrically insulating layers 16 and 18 at relatively high temperature may result in extensive growth of grains within the copper interconnect structure 14a and the resulting formation of voids 20 at grain boundaries 22. These voids 20 may operate to reduce device yield in large scale integrated circuit devices.

### SUMMARY OF THE INVENTION

Methods of forming copper interconnect structures according to embodiments of the present invention include forming an electrically insulating layer having a recess therein on a semiconductor substrate and then forming a layer of copper having a thickness greater than about 3000 Å on an upper surface of the electrically insulating layer and in the recess. The layer of copper is then annealed. This annealing step may be a relatively low temperature anneal (i.e., “soft” anneal). In particular, this annealing step may include heating the layer of copper in a process chamber having an internal temperature in a range from about 50° C. to about 200° C. After the initial anneal, the layer of copper is planarized for a sufficient duration to reduce a thickness of the layer of copper on the upper surface to a range from about 1000 Å to about 2000 Å. The planarized layer of copper is then annealed again and/or exposed to a plasma treatment. The duration and temperature of this step(s) (i.e., the total “thermal treatment”) is sufficient to cause the formation of grooves at grain boundaries within the layer of copper. This thermal treatment step may include heating the layer of copper in a process chamber having an internal temperature in a range from about 200° C. to about 500° C. Following this thermal treatment, the layer of copper is further planarized for a sufficient duration to remove the grooves and expose the upper surface of the electrically insulating layer and define a conductive copper pattern within the recess.

According to some of these embodiments, the step of forming a layer of copper includes electroplating a layer of copper onto the electrically insulating layer. This step may be preceded by a step of forming a copper electroplating seed layer within the recess. The step of forming a layer of copper may also be preceded by a step of forming an electrically conductive barrier layer that extends into the recess and onto the upper surface of the electrically insulating layer. In some embodiments, the electrically conductive barrier layer may include a tantalum nitride layer or a bilayer of tantalum and tantalum nitride. In the event a barrier layer is provided, then the step of further planarizing the layer of copper includes planarizing the layer of copper and the electrically conductive barrier layer in sequence to expose the upper surface.

Additional embodiments of the invention include methods of forming a copper interconnect structure by forming an electrically insulating layer having a contact hole therein on a semiconductor substrate and then forming an electrically conductive barrier layer comprising tantalum on sidewalls of the contact hole. This barrier layer may include a tantalum nitride layer or a bilayer of tantalum nitride and tantalum. A copper seed layer is then formed on a portion of the barrier layer extending in the contact hole. Next, a layer of copper having a thickness greater than about 3000 Å is electroplated to fill up the contact hole and also extend onto an upper surface of the electrically insulating layer. This electroplated layer of copper is then annealed. This annealing step may include heating the layer of copper in a process chamber having an internal temperature in a range from about 50° C. to about 200° C. The layer of copper is then planarized for a sufficient duration to reduce a thickness of the layer of copper on the upper surface to a range from about 1000 Å to about 2000 Å. The planarized layer of copper is then annealed again for a sufficient duration to define grooves therein at grain boundaries within the layer of copper. These grooves are then removed by planarizing the layer of copper and the electrically conductive barrier layer in sequence to expose the upper surface of the electrically insulating layer and define a conductive copper pattern within the contact hole.

### BRIEF DESCRIPTION OF THE DRAWINGS

FIGS. 1A-1D are cross-sectional views of intermediate structures that illustrate conventional methods of forming copper interconnect structures on substrates.

FIG. 2A-2F are cross-sectional views of intermediate structures that illustrate methods of forming copper interconnect structures according to embodiments of the present invention.

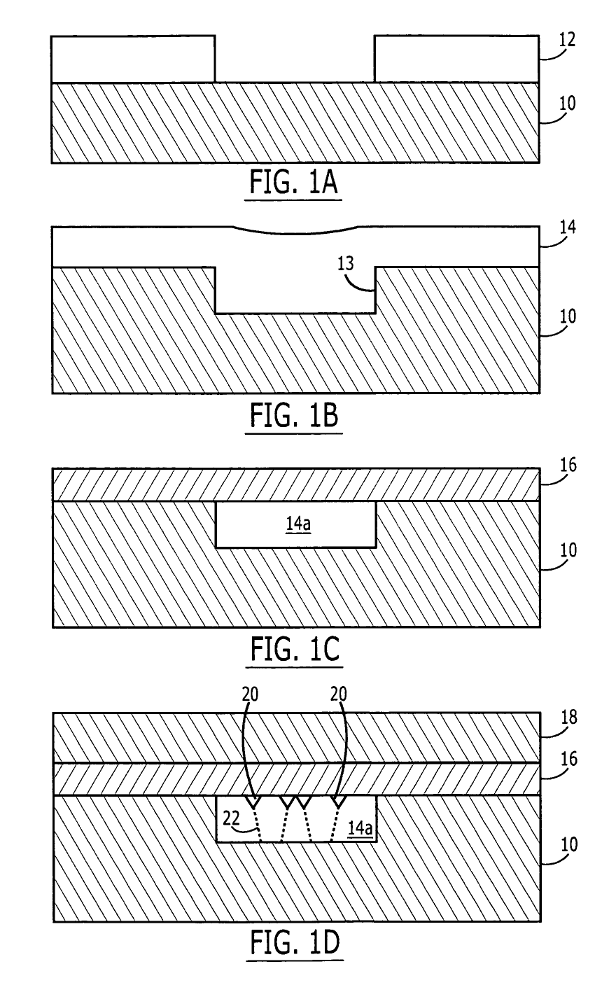

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Like numbers refer to like elements throughout.

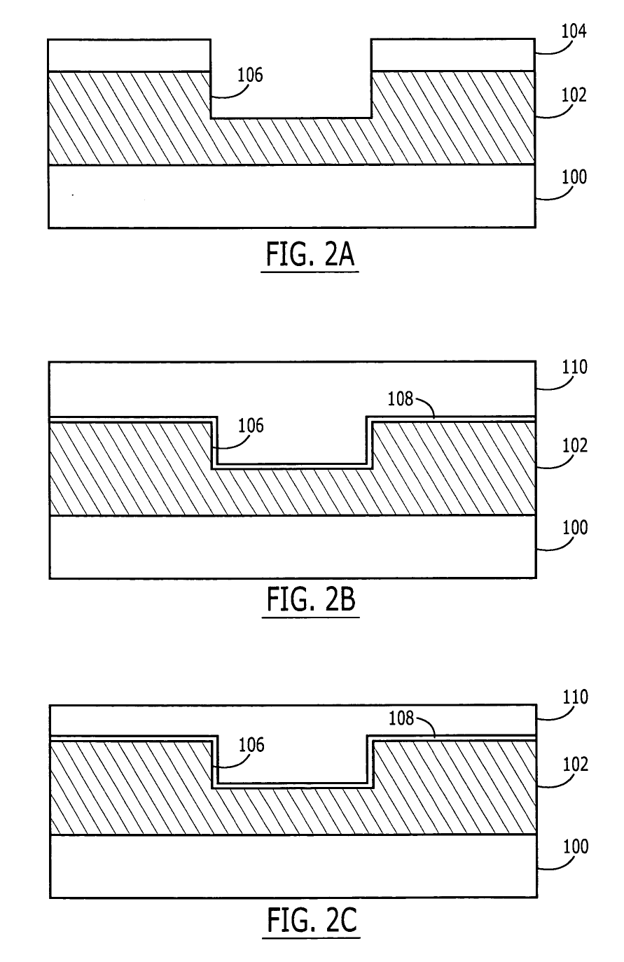

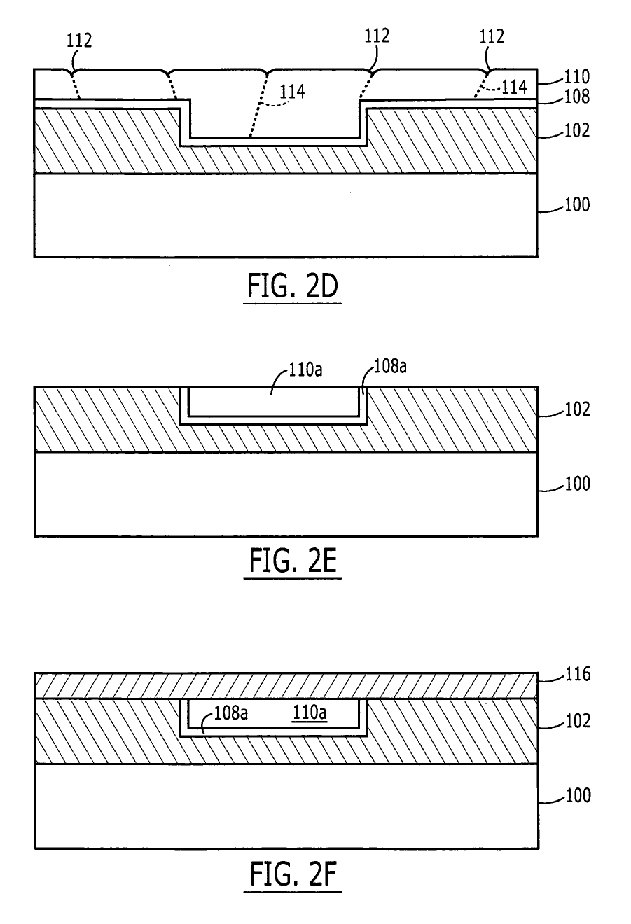

Referring now to FIG. 2A, methods of forming copper interconnect structures include the step of forming an electrically insulating layer 102 on a surface of a substrate 100. This substrate 100 may be a semiconductor substrate having active integrated circuit devices (not shown) therein. The electrically insulating layer 102 may a dielectric layer having a thickness in a range from about 1000 Å to about 10,000 Å. The electrically insulating layer 102 may be formed directly on an upper surface of the substrate 100 or one or more intervening layers, including additional electrically insulating layers, may be provided between the electrically insulating layer 102 and the substrate 100. At least one recess 106 may be formed in the electrically insulating layer 102 by patterning a layer of photoresist 104 and then etching back the electrically insulating layer 102 using the patterned layer of photoresist 104 as an etching mask. In some embodiments, the recess 106 may extend partially through the electrically insulating layer 102, however, in other embodiments the recess 106 may represent a contact hole that extends entirely through the electrically insulating layer 102. This contact hole may expose an underlying layer, which may be the substrate 100 or underlying wiring pattern or interconnect (not shown), for example.

Referring now to FIG. 2B, a blanket electrically conductive barrier layer 108 is formed on an upper surface of the electrically insulating layer 102. This barrier layer 108 also extends onto sidewalls and a bottom of the recess 106. In some embodiments of the invention, the barrier layer 108, which is optional, may be a tantalum nitride layer or a bilayer of tantalum nitride and tantalum. The barrier layer 108 may have a thickness in a range from about 10 Å to about 3000 Å. The formation of the barrier layer 108 is followed by a step of forming a copper electroplating seed layer (not shown) and then electroplating a copper layer 110 onto the barrier layer. As shown in FIG. 2B, the copper layer 110 completely fills the recess 106 and extends onto and opposite the upper surface of the substrate 100. The copper layer 110 may be formed to have a thickness in a range from about 3000 Å to about 15,000 Å.

After electroplating, the copper layer 110 undergoes a “soft” anneal at a relatively low temperature. This annealing step may be performed by heating the copper layer 110 in a process chamber having an internal temperature in a range from about 50° C. to about 200° C. for a duration of about 60 minutes. Thereafter, as illustrated by FIG. 2C, the copper layer 110 is planarized for a sufficient duration to reduce a thickness of the copper layer 110 on the upper surface of the electrically insulating layer 102 to a range from about 1000 Å to about 2000 Å. This planarization step may be performed by chemical-mechanical polishing the copper layer 110. As illustrated by FIG. 2D, an additional annealing and/or plasma treatment step is then performed on the copper layer 110. The plasma treatment step may including exposing the copper layer 110 to a NH3 plasma. This annealing and/or plasma treatment step operates as a thermal treatment step having a sufficient thermal budget to cause the formation of grooves 112 along grain boundaries 114 within the copper layer 110. In some embodiments of the invention, the thermal treatment step may include heating the copper layer 110 in a process chamber having an internal temperature in a range from about 200° C. to about 500° C. for a duration of about 30 minutes.

Referring now to FIG. 2E, the copper layer 110 and the barrier layer 108 are planarized in sequence to expose the upper surface of the electrically insulating layer 102 and thereby define an interconnect structure within the recess 106. This interconnect structure includes a copper wiring pattern 110a and an underlying barrier layer pattern 108a. As illustrated by FIG. 2F, the interconnect structure may be covered by another electrically insulating layer 116. Additional back end processing steps may then be performed to complete an integrated circuit device that utilizes the interconnect structure as an electrically conductive wiring pattern.

In the drawings and specification, there have been disclosed typical preferred embodiments of the invention and, although specific terms are employed, they are used in a generic and descriptive sense only and not for purposes of limitation, the scope of the invention being set forth in the following claims.

1. A method of forming a copper interconnect structure, comprising the steps of:
forming an electrically insulating layer having a recess therein, on a substrate;
forming a layer of copper having a thickness greater than about 3000 ÿ on an upper surface of the electrically insulating layer and in the recess;
annealing the layer of copper; then
planarizing the layer of copper for a sufficient duration to reduce a thickness of the layer of copper on the upper surface to a range from about 1000 Å to about 2000 Å; then
annealing the planarized layer of copper for a sufficient duration to define grooves therein at grain boundaries within the layer of copper; and then
further planarizing the layer of copper for a sufficient duration to expose the upper surface and define a conductive copper pattern within the recess.

2. The method of claim 1, wherein said step of forming a layer of copper comprises electroplating a layer of copper onto the electrically insulating layer.

3. The method of claim 1, wherein said step of forming a layer of copper is preceded by a step of forming an electrically conductive barrier layer comprising tantalum in the recess.

4. The method of claim 1, wherein said step of annealing the layer of copper comprises heating the layer of copper in a process chamber having a temperature in a range from about 50° C. to about 200° C.

5. The method of claim 3, wherein said step of forming an electrically conductive barrier layer comprises depositing an electrically conductive barrier layer on the upper surface; and wherein said step of further planarizing the layer of copper comprises planarizing the layer of copper and the electrically conductive barrier layer in sequence to expose the upper surface.

6. The method of claim 5, wherein said step of annealing the layer of copper comprises heating the layer of copper in a process chamber having a temperature in a range from about 50° C. to about 200° C.

7. The method of claim 1, wherein said step of forming a layer of copper is preceded by a step of forming an electrically conductive barrier layer comprising a bilayer of tantalum and tantalum nitride in the recess.

8. The method of claim 4, wherein said step of annealing the planarized layer of copper comprises heating the layer of copper in a process chamber having a temperature in a range from about 200° C. to about 500° C.

9. The method of claim 1, wherein said step of annealing the planarized layer of copper comprises heating the layer of copper in a process chamber having a temperature in a range from about 200° C. to about 500° C.

10. A method of forming a copper interconnect structure, comprising the steps of:
forming an electrically insulating layer having a recess therein on a substrate;
forming a layer of copper having a thickness greater than about 3000 Å on an upper surface of the electrically insulating layer and in the recess;
annealing the layer of copper; then
planarizing the layer of copper for a sufficient duration to reduce a thickness of the layer of copper on the upper surface to a range from about 1000 Å to about 2000 Å; then
plasma treating the layer of copper for a sufficient duration to define grooves therein at grain boundaries within the layer of copper; and then
further planarizing the layer of copper for a sufficient duration to expose the upper surface and define a conductive copper pattern within the recess.

11. The method of claim 10, wherein said step of forming a layer of copper comprises electroplating a layer of copper onto the electrically insulating layer.

12. The method of claim 10, wherein said step of forming a layer of copper is preceded by a step of forming an electrically conductive barrier layer comprising tantalum in the recess.

13. The method of claim 10, wherein said step of annealing the layer of copper comprises heating the layer of copper in a process chamber having a temperature in a range from about 50° C. to about 200° C.

14. The method of claim 12, wherein said step of forming an electrically conductive barrier layer comprises depositing an electrically conductive barrier layer on the upper surface; and wherein said step of further planarizing the layer of copper comprises planarizing the layer of copper and the electrically conductive barrier layer in sequence to expose the upper surface.

15. The method of claim 14, wherein said step of annealing the layer of copper comprises heating the layer of copper in a process chamber having a temperature in a range from about 50° C. to about 200° C.

16. The method of claim 10, wherein said step of forming a layer of copper is preceded by a step of forming an electrically conductive barrier layer comprising a bilayer of tantalum and tantalum nitride in the recess.

17. A method of forming a copper interconnect structure, comprising the steps of:
forming an electrically insulating layer having a contact hole therein on a semiconductor substrate;
forming an electrically conductive barrier layer comprising tantalum on sidewalls of the contact hole;
electroplating a layer of copper having a thickness greater than about 3000 Å onto an upper surface of the electrically insulating layer and into the contact hole;
annealing the layer of copper; then
planarizing the layer of copper for a sufficient duration to reduce a thickness of the layer of copper on the upper surface to a range from about 1000 Å to about 2000 Å; then
annealing the planarized layer of copper for a sufficient duration to define grooves therein at grain boundaries within the layer of copper; and then
planarizing the layer of copper and the electrically conductive barrier layer in sequence to expose the upper surface and define a conductive copper pattern within the contact hole.

18. The method of claim 17, wherein said step of annealing the layer of copper comprises heating the layer of copper in a process chamber having a temperature in a range from about 50° C. to about 200° C.

19. The method of claim 18, wherein said step of annealing the planarized layer of copper comprises heating the layer of copper in a process chamber having a temperature in a range from about 200° C. to about 500° C.

20. The method of claim 17, wherein said step of annealing the planarized layer of copper comprises heating the layer of copper in a process chamber having a temperature in a range from about 200° C. to about 500° C.

21. The method of claim 17, wherein the electrically conductive barrier layer comprises a bilayer of tantalum and tantalum nitride.

22. A method of forming a copper interconnect structure, comprising the steps of:
forming an electrically insulating layer having a recess therein, on a substrate;
forming a layer of copper on an upper surface of the electrically insulating layer and in the recess;
annealing the layer of copper; then
planarizing an upper surface of the layer of copper for a duration sufficient to remove at least 1000 Å therefrom, but insufficient to expose the electrically insulating layer; then
heat treating the planarized layer of copper for a sufficient duration to define grooves therein at grain boundaries within the layer of copper; and then
further planarizing the layer of copper for a sufficient duration to expose the upper surface and define a conductive copper pattern within the recess.

23. The method of claim 22, wherein said step of forming a layer of copper comprises electroplating a layer of copper onto the electrically insulating layer.

24. The method of claim 22, wherein said step of forming a layer of copper is preceded by a step of forming an electrically conductive barrier layer comprising tantalum in the recess.

25. The method of claim 22, wherein said step of annealing the layer of copper comprises heating the layer of copper in a process chamber having a temperature in a range from about 50° C. to about 200° C.

26. The method of claim 22, wherein said heat treating step comprises heating the planarized layer of copper in a process chamber having a temperature in a range from about 200° C. to about 500° C.
